(19) United States
(12) Patent Application Publication
(10) Pub. No.: US 2016/0007505 A1
(43) Pub. Date: Jan. 7, 2016

(54) SERVER HEAT DISSIPATION SYSTEM

(71) Applicant: Jong-sun KIM, Gimpo-si, Gyeonggi-do (KR)

(72) Inventor: Jong-sun KIM, Gimpo-si Gyeonggi-do (KR)

(21) Appl. No.: 14/770,326

(22) PCT Filed: Jun. 27, 2013
(86) PCT No.: PCT/KR2013/005731

§ 371 Date: Aug. 25, 2015

(30) Foreign Application Priority Data
Feb. 25, 2013 (KR) 10-2013-0019847

(51) Int. Cl. H05K 7/20

(52) U.S. Cl. CPC H05K 7/20736

(57) ABSTRACT

A heat dissipation system includes a main body part, an inner unit and a rear surface part. The main body part has first and second surfaces at both ends so as to form a receiving space therein. The inner unit is received in the receiving space through a first opening portion provided to the first surface and coupled thereto so as to be sealed. The rear surface part is coupled to the second surface so as to be sealed.

### TECHNICAL FIELD

The present invention relates to a heat dissipation system, and more particularly to a heat dissipation system which can be used in a computer server.

### BACKGROUND ART

Recently, in a server, i.e., a computer hardware which executes a server program, due to the higher performance of hardware mounted in the server, a plurality of parts or circuits sensitive to heat are complexly used. As a result, a demand for an effective heat dissipation structure increases so as to maintain the performance of the server and to improve the durability of the server.

Here, a conventional server 10 shown in FIG. 1, a body 13 located between a front portion 11 to which a hard driver is inserted and mounted and a rear portion 12 to which various ports are connected forms an outer surface case. Various hardwares are received in an inner receiving space formed by the front portion 11, rear portion 13, and body 13. The conventional server 10 has a heat dissipation structure for dissipating the inner heat by a fan positioned within the server 10 through an opening 14 formed in the body 13.

Therefore, even though the heat is dissipated by the opening 14 or the thermal conductivity of the body 13, etc., it is very difficult to dissipate all of the heat generated within the server. As a result, the server may malfunction or the durability of the server may be reduced. Particularly, this heat generation problem causes the temperature increase of an entire indoor space as well as the malfunction, etc., of the server. Therefore, a separate cooling system should be required for the entire indoor space on summer.

Recently, for the purpose of solving the problems in the heat dissipation, a technology is being developed which improves a heat dissipation effect through a circulation system including separate inlet and outlet ports and circulating the inner air. However, there are problems such as a cost for installing the circulation system, a structure complexity, etc.

### DISCLOSURE

### Technical Problem

Therefore, the technical solution of the present invention is to overcome the above problems. The object of the present invention is to provide a server heat dissipation system having an improved heat dissipation effect.

### Technical Solution

The heat dissipation system which designed to achieve the above object in accordance with an embodiment of the present invention includes a main body, an inner unit, and a rear portion. A first surface and a second surface are formed on both ends of the main body, so that an inner receiving space is formed. The inner unit is received within the receiving space through a first opening formed in the first surface and coupled to and sealed with the first surface. The rear portion is coupled to and sealed with the second surface.

In the embodiment, cooling gas for cooling the inside of the receiving space may be filled in the receiving space sealed by the main body, inner unit, and rear portion.

In the embodiment, a nozzle into which the cooling gas is introduced may be formed in the rear portion.

In the embodiment, the cooling gas may be nitrogen gas.

In the embodiment, a first groove may be formed in the first surface, and a second groove may be formed in the second surface.

In the embodiment, a third groove corresponding to the first groove may be formed in the inner unit, and a fourth groove corresponding to the second groove may be formed in the rear portion.

In the embodiment, the heat dissipation system may further include a first sealing portion which is inserted the first groove and the third groove and seals between the main body and the inner unit, and a second sealing portion which is inserted the second groove and the fourth groove and seals between the main body and the rear portion.

In the embodiment, the first and second sealing portions may be a rubber ring respectively.

In the embodiment, the first and second sealing portions may be made of a sealing material respectively.

In the embodiment, the heat dissipation system may further include a substrate which is connected to the rear portion and is received within the receiving space through a second opening formed in the second surface, and a plurality of connection terminals which are mounted on the substrate and are connected respectively to external terminals through the rear portion.

In the embodiment, the heat dissipation system may further include cover units which cover the plurality of connection terminals respectively and are coupled to and sealed with the substrate and the rear portion.

In the embodiment, a cover groove may be formed in the front of the cover unit, which is opposite to the rear portion, and a rear groove corresponding to the cover groove may be formed in the rear portion.

In the embodiment, the cover unit may include a cover sealing portion which is inserted between the cover groove and the rear groove and seals between the cover unit and the rear portion.

In the embodiment, the cover sealing portion may be a rubber ring.

In the embodiment, connection ports of the connection terminals may be exposed to the outside through openings of the front and rear portion.

In the embodiment, a sealing material may be sealed between the substrate and the cover unit.

In the embodiment, the substrate, the rear portion, and the connection terminals may be sealed with the sealing material respectively.

In the embodiment, the sealing material may cover the entire outside of the connection terminal.

In the embodiment, the sealing material may be an epoxy resin.

### Advantageous Effects

According to the embodiments of the present invention, since the main body, the inner unit, and the rear portion of the heat dissipation system are coupled to and sealed with each other and cooling gas is filled in the heat dissipation system, there is no necessity of a separate heat dissipation system and it is possible to easily cool the inside of the server by means of a simple structure. Particularly, since nitrogen gas is used as the cooling gas, various inner electronic elements, electric wires, circuit boards, etc., are able to maintain an excellent cooling effect without malfunction.

Also, a rubber ring or a sealing material like an epoxy resin, etc., is used as the first and first sealing portions for sealing the heat dissipation system. Therefore, through the simple structure and excellent sealing effect, it is possible to minimize the leakage of the filled nitrogen gas.

Also, the nozzle into which the cooling gas is introduced is formed in the rear portion, so that the initial or additional introduction of the cooling gas is easily performed. Accordingly, the density of the cooling gas within the receiving space can be uniformly maintained.

Also, through the cover unit having a simple structure which covers the connection terminal and is sealed by the rear portion and the cover sealing portion, a connection relationship between the connection terminals mounted on the substrate and the external terminals can be maintained, and the excellent sealing effect of the inside of the receiving space can be maintained.

On the other hand, the fronts of the connection terminals are covered by the sealing material with the omission of the cover unit, so that the excellent sealing effect can be maintained.

### BRIEF DESCRIPTION OF DRAWINGS

FIG. 1 is a perspective view showing a conventional server;

FIG. 2 is an exploded perspective view showing a heat dissipation system according to an embodiment of the present invention;

FIG. 3 is a front view showing a rear portion of the heat dissipation system of FIG. 2 as viewed in a direction of “A”;

FIG. 4 is an exploded perspective view showing a portion of “B” of the heat dissipation system of FIG. 2;

FIG. 5 is an exploded perspective view showing a heat dissipation system according to another embodiment of the present invention; and

FIG. 6 is a cross sectional view taken along line I-I′ of FIG. 5.

* REFERENCE NUMERALS

| | |
|---|---|
| 100: heat dissipation system | 110: body |
| 120: first surface | 130: second surface |
| 140: first sealing part | 141: second sealing part |
| 150: inner unit | 160: substrate |
| 170: a first cover unit | 175: second cover unit |
| 182: second cover | 184: second cover groove |
| 185: second cover ring | 190: rear portion |
| 192: fourth groove | 193: nozzle |
| second opening | 199: outer groove |

### BEST MODE

As the present invention can have various shapes as well as can be diversely changed, embodiments will be illustrated in the drawings and described in detail. While the present invention is not limited to particular embodiments, all modification, equivalents and substitutes included in the spirit and scope of the present invention are understood to be included therein. In the drawings, similar reference numerals are used to designate similar components. While terms such as the first and the second, etc., can be used to describe various components, the components are not limited by the terms mentioned above.

The terms are used only for distinguishing between one component and other components. Terms used in the present specification are provided for description of only specific embodiments of the present invention, and not intended to be limiting. An expression of a singular form includes the expression of plural form thereof unless otherwise explicitly mentioned in the context.

In the present specification, it should be understood that the term “include” or “be formed” and the like is intended to specify characteristics, numbers, steps, operations, components, parts or any combination thereof which are mentioned in the specification, and intended not to previously exclude the possibility of existence or addition of at least one another characteristics, numbers, steps, operations, components, parts or any combination thereof.

Unless differently defined, all terms used herein including technical and scientific terms have the same meaning as commonly understood by one of ordinary skill in the art to which the present invention belongs. Terms, for example, commonly used terms defined in the dictionary, are to be construed to have exactly the same meaning as that of related technology in the context. As long as terms are not clearly defined in the present application, the terms should not be ideally or excessively construed as formal meaning.

Hereafter, the embodiment of the present invention will be described in more detail with reference to the accompanying drawings.

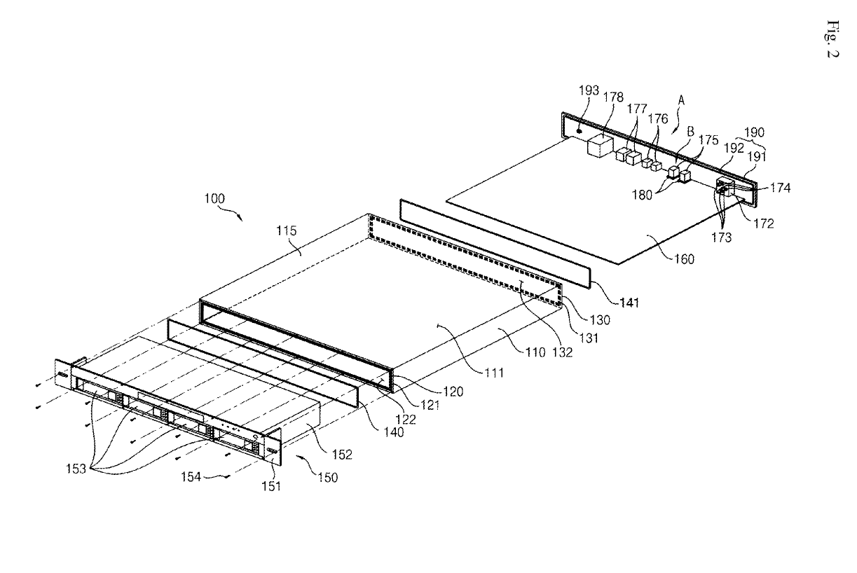

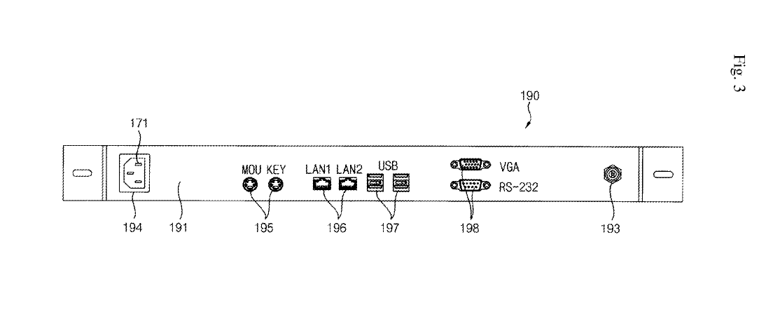

FIG. 2 is an exploded perspective view showing a heat dissipation system according to an embodiment of the present invention. FIG. 3 is a front view showing a rear portion of the heat dissipation system of FIG. 2 as viewed in a direction of “A”.

Referring to FIGS. 2 and 3, the heat dissipation system 100 according to the embodiment of the present invention includes a main body 110, a first sealing portion 140, a second sealing portion 141, an inner unit 150, a substrate 160, a plurality of connection terminals 171, MOU, KEY, LAN1, LAN2, USB, VGA, and RS-232, cover units 170, 175, 176, 177, and 178, and a rear portion 190.

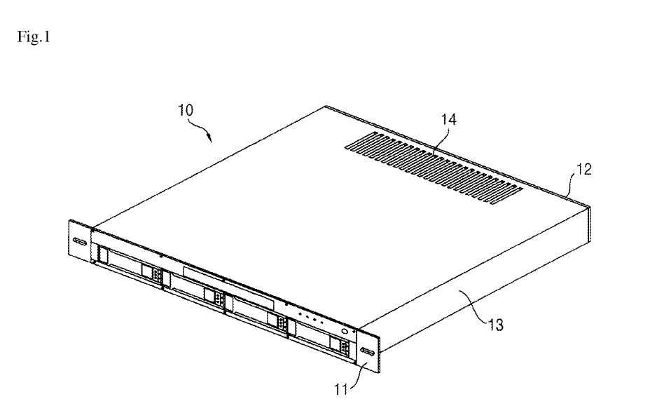

The structure and shape of the heat dissipation system 100 are substantially the same as those of a common server 10 shown in FIG. 1 with the exception of a separate internal structure for heat dissipation. Also, although the embodiment describes that the heat dissipation system 100 is applied to the server shown in FIG. 1, it is obvious that the heat dissipation system 100 can be applied to not only the server, but also various structures requiring the heat dissipation.

The main body 110 may include a first surface 120 and a second surface 130 which are formed on opposite ends thereof. The main body 110 may have a flat square pillar shape forming a receiving space 111 therewithin.

The first surface 120 may have a quadrangular shape. A first opening 122 is formed in the central portion of the first surface 120. The first surface 120 is connected to the receiving space 111 through the first opening 122. In this case, the first opening 122 may also have a quadrangular shape. The first opening 122 may be formed apart from four corners of the first surface 120 by a certain distance.

Also, a first groove 121 is formed to a predetermined depth in the first surface 120. The first groove 121 may also have a quadrangular shape and may be formed apart from four corners of the first surface 120 and four corners of the first opening 122 by a certain distance.

Likewise, the second surface 130 may also have a quadrangular shape. A second opening 132 is formed in the central portion of the second surface 130. The second surface 130 is connected to the receiving space 111 through the second opening 132. In this case, the second opening 132 may also have a quadrangular shape. The second opening 132 may be formed apart from four corners of the second surface 130 by a certain distance.

Also, a second groove 131 is formed to a predetermined depth in the second surface 130. The second groove 131 may also have a quadrangular shape and may be formed apart from four corners of the second surface 130 and four corners of the second opening 132 by a certain distance.

Meanwhile, the main body 110 may be integrally made of a metallic material. That is, it is desirable that the main body 110 is originally integrally formed as one unit instead of being formed by combining a plurality of units. Thus, the main body 110 includes no opening other than the first and second openings 122 and 132, and has a minimized gap or originally has no gap, so that it is possible to minimize the leakage of gas filled in the main body.

The inner unit 150 includes a front portion 151, an inner body 152, a plurality of hard disks 153, and a coupling unit 154 and is received within the receiving space 111 of the main body 110. The inner unit 150 is a frame which receives the hard disks 153 and is received within the main body 110. Control buttons of the hard disks 153 are exposed through the front portion 151. All of the hard disks 153 are received in an internal space formed by the inner body 152.

In this case, as with the main body 110, the inner body 152 is integrally formed, and thus, it has a minimized gap or originally has no gap.

Meanwhile, though not shown in FIG. 2, in an inner surface of the front portion 151 of the inner unit 150, a third groove is formed at a position which is opposite to and corresponds to the first groove 121. Here, the size and shape of the third groove may be symmetrical with those of the first groove 121.

The first sealing portion 140 is located between the first groove 121 and the third groove. When the main body 110 is coupled to the inner unit 150, the first sealing portion 140 is inserted between the first groove 121 and the third groove, thereby sealing the portion where the main body 110 and the inner unit 150 have been coupled. Therefore, gas filled therein does not leak through the coupling portion between the main body 110 and the inner unit 150.

In this case, the first sealing portion 140 may be a rubber ring so as to increase a sealing force. Unlike this, the first sealing portion 140 may be made of a sealing material. When the first sealing portion 140 is made of a sealing material, it is desirable that the sealing material is filled in the first groove 121 and the third groove without any gap. Also, an epoxy resin having an excellent sealing force and excellent durability may be used as the sealing material.

The rear portion 190 is coupled to the second surface 130 of the main body 110. The rear portion 190 may have a quadrangular shape. The substrate 160 is coupled to the rear portion 190. When the rear portion 190 is coupled to the second surface 130, the substrate 160 is received within the receiving space 111.

Meanwhile, a circuit is formed on the substrate 160. The substrate 160 may be a printed circuit board on which various electronic elements are mounted. The plurality of connection terminals are mounted on the substrate 160.

A fourth groove 192 of the rear portion 190 is formed in a surface which is opposite to the second surface 130. The size and shape of the fourth groove 192 may be symmetrical with those of the second groove 131.

The second sealing portion 141 is located between the second groove 131 and the fourth groove 192. When the main body 110 is coupled to the rear portion 190, the second sealing portion 141 is inserted between the second groove 131 and the fourth groove, thereby sealing the portion where the main body 110 and the rear portion 190 have been coupled. Therefore, gas filled therein does not leak through the coupling portion between the main body 110 and the rear portion 190.

In this case, as with the first sealing portion 140, the second sealing portion 141 may be a rubber ring so as to increase a sealing force. Unlike this, the second sealing portion 141 may be made of a sealing material. When the second sealing portion 141 is made of a sealing material, it is desirable that the sealing material is filled in the second groove 131 and the fourth groove 192 without any gap. Also, an epoxy resin having an excellent sealing force and excellent durability may be used as the sealing material.

Here, even though the main body 110, the inner unit 150, and the rear portion 190 are coupled to and sealed with each other, a server to which the heat dissipation system 100 according to the embodiment of the present invention is applied may further require that the plurality of connection terminals 171, MOU, KEY, LAN1, LAN2, USB, VGA, and RS-232 are sealed.

Referring to FIG. 3, in order that external terminals (not shown) are connected to the plurality of connection terminals 171, MOU, KEY, LAN1, LAN2, USB, VGA, and RS-232, first to fifth openings 194, 195, 196, 197, and 198 which correspond to the connection terminals respectively are formed in a rear surface 191. As a result, the connection terminals are exposed to the outside respectively through the first to the fifth openings 194, 195, 196, 197, and 198.

However, since the connection terminals 171, MOU, KEY, LAN1, LAN2, USB, VGA, and RS-232 are exposed to the outside by the first to the fifth openings 194, 195, 196, 197, and 198, a separate sealing means is required.

In the embodiment, the cover units 170, 175, 176, 177, and 178 cover the outsides of the connection terminals 171, MOU, KEY, LAN1, LAN2, USB, VGA, and RS-232, so that the receiving space 111 is sealed from the outwardly exposed connection terminals 171, MOU, KEY, LAN1, LAN2, USB, VGA, and RS-232.

For example, the first cover unit 170 covers the outside of the power terminal 171. The second cover unit 175 covers the mouse terminal MOU and the keyboard terminal KEY respectively. The third cover unit 176 covers the first and second LAN terminals LAN 1 and LAN2 respectively. The fourth cover unit 177 covers the USB terminal USB. The fifth cover unit 178 covers the VGA terminal VGA and the RS-232 terminal RS-232.

In the meantime, the connection terminals shown in FIGS. 2 to 3, are only examples. Various kinds of the connection terminals may be added. In this case, the outsides of the added connection terminals are covered by added cover units respectively, so that the receiving space 111 can be sealed.

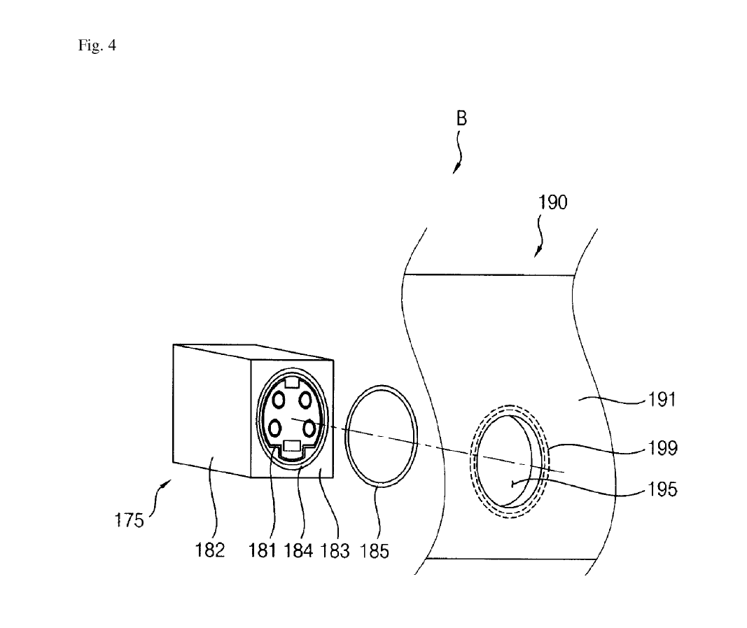

In this case, a method in which the cover units 170, 175, 176, 177, and 178 seal the connection terminals 171, MOU, KEY, LAN1, LAN2, USB, VGA, and RS-232 respectively will be described in detail with reference to later-described FIG. 4.

However, when the cover units 170, 175, 176, 177, and 178 are mounted on the substrate 160, the sealing may not be done between the substrate 160 and the cover units 170, 175, 176, 177, and 178. Therefore, as shown in FIG. 2, a contact portion between the second cover unit 175 and the substrate 160 may be sealed by means of a second cover seal ring 180.

In this case, the second cover seal ring 180 may be, as described above, made of a sealing material like an epoxy resin. Also, though not shown, the cover seal ring may be formed on a contact portion between the substrate 160 and the cover units 170, 176, 177, and 178 other than the second cover unit 175.

Furthermore, while some terminals, e.g., the power terminal 171, of the connection terminals 171, MOU, KEY, LAN1, LAN2, USB, VGA, and RS-232 are mounted on the substrate 160, a separate terminal 173 may protrude toward the receiving space 111, i.e., the outside of the first cover unit 170. In this case, the separate terminal 173 protrudes outwardly from a first cover 172 of the first cover unit 170, so that a gap may be created in the outer surface of the first cover 172. Therefore, the minute gap which may be created in the outer surface of the first cover 172 by the protrusion of the separate terminal 173 can be sealed by a first cover seal ring 174.

In this case, the first cover seal ring 174 may be also, as described above, made of a sealing material like an epoxy resin, etc.

The first cover seal ring 174 is applied to the first cover 172. Besides, when the separate terminals protruding toward the receiving space 111 are formed, the first cover seal ring 174 may be additionally formed on the outer surface of the other cover units 175, 176, 177, and 178.

As described above, the main body 110 is coupled to the inner unit 150 and the rear portion 190 respectively, and then is sealed by the first and second sealing portions 140 and 141. Also, the openings 194, 195, 196, 197, and 198 formed in the rear portion 190 are sealed by the first to the fifth cover units 170, 175, 176, 177, and 178. Thus, the receiving space 111 is sealed from the outside.

Therefore, in the embodiment, cooling gas 115 is filled in the sealed receiving space 111. In this case, the cooling gas 115 may be filled through a nozzle 193 formed in the rear portion 190. After all of the air in the receiving space 111 are exhausted and removed, the cooling gas 115 is filled.

In this case, the cooling gas 115 may be nitrogen gas which has an excellent cooling effect, minimizes the malfunctions of inner electrical elements, an electrical circuit, etc., and has an excellent electrical and thermal stability.

Accordingly, in the embodiment, the receiving space 111 is sealed and the cooling gas is filled in the receiving space 111. Therefore, a separate heat dissipation structure and heat dissipation unit are removed, and then an effective heat dissipation system can be completed.

FIG. 4 is an exploded perspective view showing a portion of “B” of the heat dissipation system of FIG. 2. In FIG. 4, a structure and a method in which the cover units 170, 175, 176, 177, and 178 seal the connection terminals 171, MOU, KEY, LAN1, LAN2, USB, VGA, and RS-232 respectively will be described by taking the second cover unit 175 and the mouse terminal MOU as an example. In this case, since the structure and the method in which the second cover unit 175 seals the mouse terminal MOU is substantially the same as those in which the other cover units 170, 176, 177, and 178 seal the connection terminals 171, KEY, LAN1, LAN2, USB, VGA, and RS-232 respectively, a repetitive description thereof will be omitted.

Referring to FIG. 4, the second cover unit 175 includes a second cover 182, a second cover front 183, a second cover groove 184, and a second cover sealing portion 185.

The second cover 182 covers the outside of the mouse terminal MOU and has an inner space for receiving the mouse terminal MOU. The second cover 182 may have a square pillar shape.

In the second cover 182, the second cover front 183 facing the rear portion 190 has an opening for allowing a mouse port 181 of the mouse terminal MOU to be exposed. The second cover groove 184 is formed to a predetermined depth around the opening.

The second cover groove 184 may be formed apart from the opening at a certain interval along the circumference of the opening. Since the mouse terminal MOU has a circular shape, the opening has a circular shape, and accordingly, the second cover groove 184 may also have a circular shape.

Meanwhile, a rear groove 199 is formed in an inner surface of the rear portion 190. The rear groove 199 has a size and shape which are opposite and corresponds to the second cover groove 184.

The second cover sealing portion 185 is inserted between the second cover groove 184 and the rear groove 199 and seals between the second cover unit 175 and the rear portion 190. In this case, the second cover sealing portion 185 may be a rubber ring or may be made of a sealing material. When the second cover sealing portion 185 is made of a sealing material, the sealing material may be an epoxy resin.

As described above, even though the mouse terminal MOU is exposed to the outside through the second opening 195, the cooling gas filled in the receiving space 111 does not leak because the second cover unit 175 covering the outside of the mouse terminal MOU is coupled to and sealed with the rear portion 190.

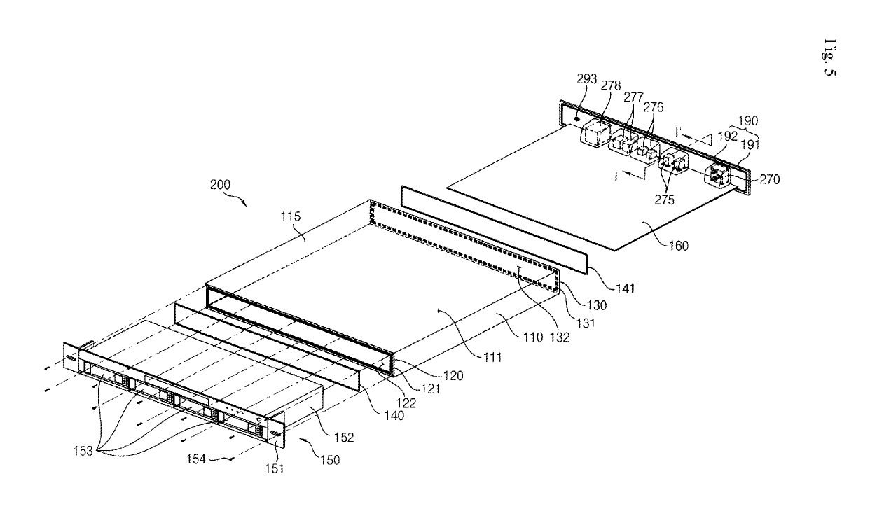

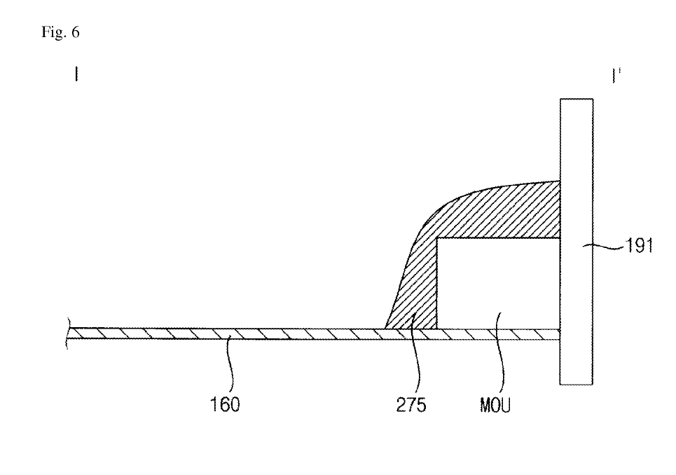

FIG. 5 is an exploded perspective view showing a heat dissipation system according to another embodiment of the present invention. FIG. 6 is a cross sectional view taken along line I-I′ of FIG. 5.

Since the heat dissipation system 200 according to the embodiment of the present invention is substantially the same as the heat dissipation system 100 described with reference to FIGS. 2 to 4 with the exception of a method of sealing the connection terminals 171, MOU, KEY, LAN1, LAN2, USB, VGA, and RS-232 respectively, the same reference numerals will be assigned and a repetitive description thereof will be omitted.

Referring to FIGS. 5 and 6, in the heat dissipation system 200, the connection terminals 171, MOU, KEY, LAN1, LAN2, USB, VGA, and RS-232 are sealed respectively by first to fifth sealing portions 270, 275, 276, 277, and 278.

Specifically, the power terminal 171 is covered by the first sealing portion 270, so that gaps between the power terminal 171 and the substrate 160 and between the power terminal 171 and rear portion 190 are sealed. Likewise, the mouse terminal MOU and the keyboard terminal KEY are covered by the second sealing portion 275, so that a gap between the substrate 160 and the rear portion 190 is sealed. Also, the first and second LAN terminals LAN 1 and LAN2 are covered by the third sealing portion 276, so that a gap between the substrate 160 and the rear portion 190 is sealed. Also, the USB terminal USB is covered by the fourth sealing portion 277, so that a gap between the substrate 160 and the rear portion 190 is sealed. Also, the VGA terminal VGA and the RS-232 terminal RS-232 are covered by the fifth sealing portion 278, so that a gap between the substrate 160 and the rear portion 190 is sealed.

That is, in the embodiment, separate cover units are omitted and the connection terminals are directly covered by the first to the fifth sealing portions, so that the gaps and space are sealed. In this case, the first to the fifth sealing portions 270, 275, 276, 277, and 278 may be made of a sealing material. The sealing material may be an epoxy resin.

Meanwhile, as shown in FIG. 6, the second sealing portion 275 may be formed to sufficiently cover the gaps in the side and top of the mouse terminal MOU. Though not shown, the other sealing portions are able to cover the other connection terminals substantially in the same manner.

According to the embodiments described above, the main body, the inner unit, and the rear portion of the heat dissipation system are coupled to and sealed with each other and the cooling gas is filled in the heat dissipation system, so that a separate there is no necessity of a separate heat dissipation system and it is possible to easily cool the inside of the server by means of a simple structure. Particularly, since nitrogen gas is used as the cooling gas, various inner electronic elements, electric wires, circuit boards, etc., are able to maintain an excellent cooling effect without malfunction.

Also, a rubber ring or a sealing material like an epoxy resin, etc., is used as the first and first sealing portions for sealing the heat dissipation system. Therefore, through the simple structure and excellent sealing effect, it is possible to minimize the leakage of the filled nitrogen gas.

Also, the nozzle into which the cooling gas is introduced is formed in the rear portion, so that the initial or additional introduction of the cooling gas is easily performed. Accordingly, the density of the cooling gas within the receiving space can be uniformly maintained.

Also, through the cover unit having a simple structure which covers the connection terminal and is sealed by the rear portion and the cover sealing portion, a connection relationship between the connection terminals mounted on the substrate and the external terminals can be maintained, and the excellent sealing effect of the inside of the receiving space can be maintained.

On the other hand, the fronts of the connection terminals are covered by the sealing material with the omission of the cover unit, so that the excellent sealing effect can be maintained.

### INDUSTRIAL APPLICABILITY

The heat dissipation system according to the embodiment of the present invention can be applied to the heat dissipation of a computer server.

1. A heat dissipation system comprising:
a main body which has a first surface and a second surface formed on both ends thereof and forms an inner receiving space;
an inner unit which is received within the receiving space through a first opening formed in the first surface and is coupled to and sealed with the first surface; and
a rear portion which is coupled to and sealed with the second surface.

2. The heat dissipation system of claim 1, wherein cooling gas for cooling an inside of the receiving space is filled in the receiving space sealed by the main body, the inner unit, and the rear portion.

3. The heat dissipation system of claim 2, wherein a nozzle into which the cooling gas is introduced is formed in the rear portion.

4. The heat dissipation system of claim 2, wherein the cooling gas is nitrogen gas.

5. The heat dissipation system of claim 1, wherein a first groove is formed in the first surface, and a second groove is formed in the second surface.

6. The heat dissipation system of claim 5, wherein a third groove corresponding to the first groove is formed in the inner unit, and a fourth groove corresponding to the second groove is formed in the rear portion.

7. The heat dissipation system of claim 6, further comprising a first sealing portion which is inserted the first groove and the third groove and seals between the main body and the inner unit, and a second sealing portion which is inserted the second groove and the fourth groove and seals between the main body and the rear portion.

8. The heat dissipation system of claim 7, wherein the first and second sealing portions are a rubber ring respectively.

9. The heat dissipation system of claim 7, wherein the first and second sealing portions is made of a sealing material respectively.

10. The heat dissipation system of claim 1, further comprising a substrate which is connected to the rear portion and is received within the receiving space through a second opening formed in the second surface, and a plurality of connection terminals which are mounted on the substrate and are connected respectively to external terminals through the rear portion.

11. The heat dissipation system of claim 10, further comprising cover units which cover the plurality of connection terminals respectively and are coupled to and sealed with the substrate and the rear portion.

12. The heat dissipation system of claim 11, wherein a cover groove is formed in the front of the cover unit, which is opposite to the rear portion, and a rear groove corresponding to the cover groove is formed in the rear portion.

13. The heat dissipation system of claim 12, wherein the cover unit comprises a cover sealing portion which is inserted between the cover groove and the rear groove and seals between the cover unit and the rear portion.

14. The heat dissipation system of claim 13, wherein the cover sealing portion is a rubber ring.

15. The heat dissipation system of claim 12, wherein connection ports of the connection terminals are exposed to the outside through openings of the front and rear portion.

16. The heat dissipation system of claim 11, wherein a sealing material is sealed between the substrate and the cover unit.

17. The heat dissipation system of claim 10, wherein the substrate, the rear portion, and the connection terminals are sealed with a sealing material respectively.

18. The heat dissipation system of claim 17, wherein the sealing material covers the entire outside of the connection terminal.

19. The heat dissipation system of claim 9, 16, or 17, wherein the sealing material is an epoxy resin.

20. The heat dissipation system of claim 16, wherein the sealing material is an epoxy resin.

21. The heat dissipation system of claim 17, wherein the sealing material is an epoxy resin.
